(19) United States
(12) Patent Application Publication
(10) Pub. No.: US 2014/0347819 A1
(43) Pub. Date: Nov. 27, 2014

(54) Electronics Module for a Vehicle

(71) Applicant: Robert Bosch GmbH, Stuttgart (DE)

(72) Inventor: Harald Ott, Freiberg Am Neckar (DE)

(21) Appl. No.: 14/367,018

(22) PCT Filed: Oct. 23, 2012
(86) PCT No.: PCT/EP2012/070934

§ 371 Date: Jun. 19, 2014

(30) Foreign Application Priority Data
Dec. 21, 2011 (DE) 10 2011 089 474.8

(51) Int. Cl. B60R 16/023; H05K 7/20; F16H 61/00; H05K 5/00

(52) U.S. Cl. CPC B60R 16/0231; H05K 5/0082; H05K 7/20418; F16H 61/0003
USPC 361/714; 361/728

(57) ABSTRACT

An electronics module for a vehicle includes a plate element, a circuit carrier element, and a cover element. The electronics module further includes an inner region and an outer region. The plate element is configured to provide at least one conductive connection between the inner region and the outer region in order to electrically connect the circuit carrier element. The circuit carrier element is positioned on the cover element, and at least one electrical connection element is positioned between the circuit carrier element and the plate element. The at least one electrical connection element is an automatic connection element which is configured to automatically provide an electrically conductive connection between the circuit carrier element and the conductive connection of the plate element when the cover element and the plate element are fitted.

The present invention relates to electronics modules for vehicles. In particular, the present invention relates to an electronics module for controlling a transmission part or a transmission component. The electronics module can be arranged, in particular in the transmission here. In addition, the present invention relates to an electronics module, in particular for operation in transmission fluid, a transmission control unit for a vehicle, a transmission for a vehicle and a vehicle, in particular a motor vehicle.

### PRIOR ART

Known electronics modules for vehicles are usually implemented as hermetically sealed assemblies. In this context, a steel housing is usually used which has contact pins which are positioned in the housing wall by means of a vitrified seal and therefore connect the inner region and the outer region of the electronics module in a conductive fashion.

Electrical connecting equipment which leads on further to the individual functional elements of the electronics module, for example, sensors and plug connectors, are usually implemented with what are referred to as stamped gratings or else with cable connections, in particular in the case of functional elements which are a long way from one another.

Known electronics modules are usually composed of electronic components arranged on a component carrier which is in turn mounted on a module circuit board, for example bonded thereon, and then placed in electrical contact therewith. In this context, bonding, soldering or conductive adhesion is used for example.

In order to protect the components, a cover is finally fitted onto the printed circuit board and sealed, for example, by means of an elastomer ring or a plastic bead. The attachment of the cover and module circuit board is carried out either by means of the adhesive bead or by means of additional mechanical fastening elements, for example, rivets.

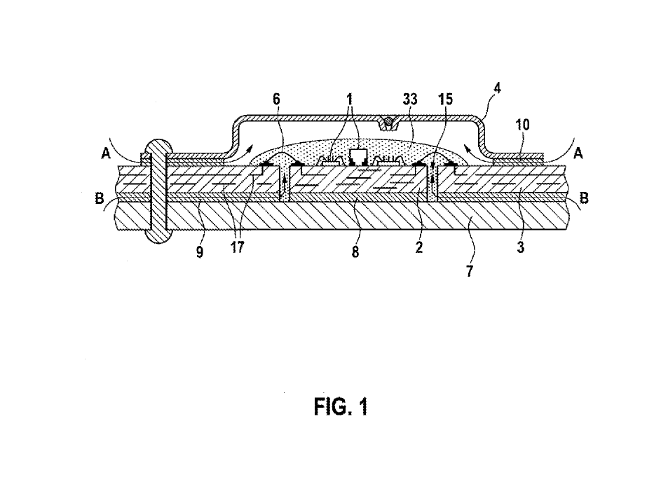

FIG. 1 shows a further exemplary refinement of a conventional electronics module. In this context, a layered structure is implemented in such a way that a plate element 3 is mounted on a carrier element 7, and a covering element 4 is mounted on said plate element 3. By way of example, an aluminum plate with 3-4 mm plate thickness can be used as the carrier element 7. A circuit carrier element 2 with electronic components 1 is mounted on the carrier element 7 in a recess 15 of the plate element 3 and is bonded onto the carrier element 7 with a thermal conductive adhesive 8, for example Q1. The circuit carrier element 2 can be implemented here as a low-temperature cofired ceramic (LTCC) or a micro circuit board.

The plate element 3 has a recess 15 into which the circuit carrier element 2 can be introduced. The plate element 3 is bonded onto the carrier element using adhesive 9, as a liquid or as an adhesive tape, in an oil-tight fashion over a large surface or only partially in the region of the circuit carrier element 2 and of the covering element 4. The inner region can be filled at least partially with a casting material 33.

The plate element 3 implements the electrical connecting equipment between the inner region of the electronics module and the electronic component 1 arranged there and the outer functional elements such as, for example, plugs and sensors which are, however, not illustrated in FIG. 1. For this purpose, conductor elements 17 can be provided in the interior of the plate element 3, said conductor elements 17 being connected to the elements 1 of the circuit carrier element 2 using connecting elements 6, for example, bonds.

In order to protect the electronic component 1 and the connecting elements 6 against transmission oil, metal chips as well as conductive deposits in the transmission oil, a covering element 4 is fastened to the plate element 3 using a sealing and bonding connection 10. Compared to the previously described exemplary refinement of a known electronics module, the electronics module according to FIG. 1 permits improved outputting of dissipated heat generated in the interior of the electronics module, but the electronics module in FIG. 1 has two possible leakage paths for transmission oil for structural reasons. Path A here constitutes the seal 10 between the covering element 4 and the plate element 3, while path B relates to the seal 9 between the plate element 3 and the carrier element 7.

As a result of, for example different thermal expansion of the plate element 3 and the carrier element 7, the adhesion 9 over a large area can be subjected to shearing stress, which can lead, for example, to partial failure as a result of delamination and degradation of the seal. During the fitting process, the possibly sensitive circuit carrier element 2 of the electronic component is bonded onto the carrier element 7 during the module fitting process, and cured. If a thermal process is required for the curing, the entire module must run through the process.

### DISCLOSURE OF THE INVENTION

One aspect of the present invention can be considered that an electronics module is made available which makes available on the one hand, good conduction away of dissipated heat from electronic components arranged in the interior of the electronics module, while the mechanical design of the electronics module has only one sealing point at the housing or at the covering element, while at the same time involving little expenditure and using proven and known components.

Accordingly, an electronics module for a vehicle, a transmission control unit, a transmission and a vehicle, in particular a motor vehicle, according to the independent claims is disclosed. Preferred refinements can be found in the dependent claims.

The electronics module according to the invention is conceived here in such a way that the circuit carrier element is arranged in the covering element and is in thermally conductive contact therewith, for example is bonded thereto, in particular, with a thermally conductive adhesive. Compared to known electronics modules, the circuit carrier element is therefore not mounted on the plate element but instead on the covering element.

The covering element preferably can be composed of a metal here and therefore serve to perform preferred outputting of the dissipated heat generated by the circuit carrier element.

The plate element with internally arranged conductor elements 17 is also used to provide contact between the electronic components in the interior of the electronics module and external sensors, actuators and the like.

In this context it is possible to configure a suitable board-to-board connection between the circuit carrier element and the plate element, which connection automatically makes available a connection between the electronic components of the circuit carrier element and the conductor elements of the plate element during the process of fitting the covering element onto the plate element.

In this context, the term automatic can be understood as meaning, in particular, that during the fitting the two elements comprising the covering element and the plate element are placed in the state in which they are to be mounted or their relative arrangement with respect to one another and at the same time the electrical connection between the circuit carrier element and the plate element is produced automatically, that is to say without a separate connecting process such as is required, for example, with bonds or cable connections. Suitable board-to-board connections which automatically connect the circuit carrier element and the plate element are, for example, suitable plug connections having a plug element and a socket element which are arranged on the circuit carrier element or the plate element. As a result, the fitting of the covering element and the plate element brings about the automatic connection, for example, through automatic plugging of a plug element into the socket element of the board-to-board connection.

After mounting on the covering element, a circuit carrier element can be subsequently cast with a suitable gel. In this context, the connecting elements of the board-to-board connection can protrude out from the gel and as a result permit the circuit carrier element which is cast in the covering element to be checked. During the subsequent fitting on the plate element, the inventive board-to-board connection permits a conductive connection to be automatically produced between the circuit carrier element and the plate element in the same manufacturing step as the sealed fitting of the covering element on the plate element. Corresponding connecting technology for the inventive board-to-board connection constitutes here sprung or tolerance-compensating plug connectors which can also have at the same time a self-centering property.

For example, in the case of a metallic covering element and a heat sink which is mounted thereon it is preferably possible to output dissipated energy or dissipated heat of the electrical components of the circuit carrier element via this metallic covering element and the heat sink which is provided if appropriate. The electronics module according to the invention is therefore also suitable for high-current applications such as, for example, actuating electrical oil pumps in a transmission.

Embodiments of the invention are illustrated in the drawings and explained in more detail in the following description, in which:

FIG. 1 shows a conventional electronics module;

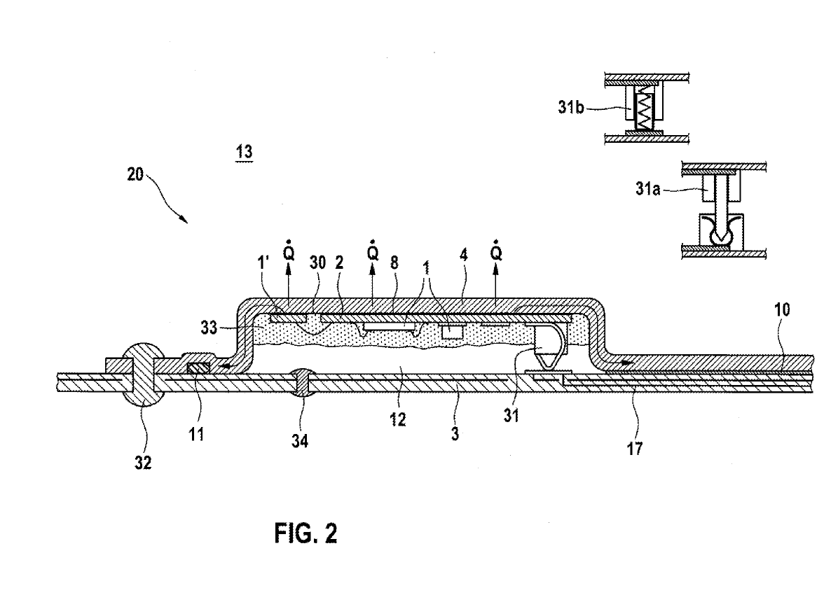

FIGS. 2-4 show exemplary refinements of an electronics module according to the present invention; and

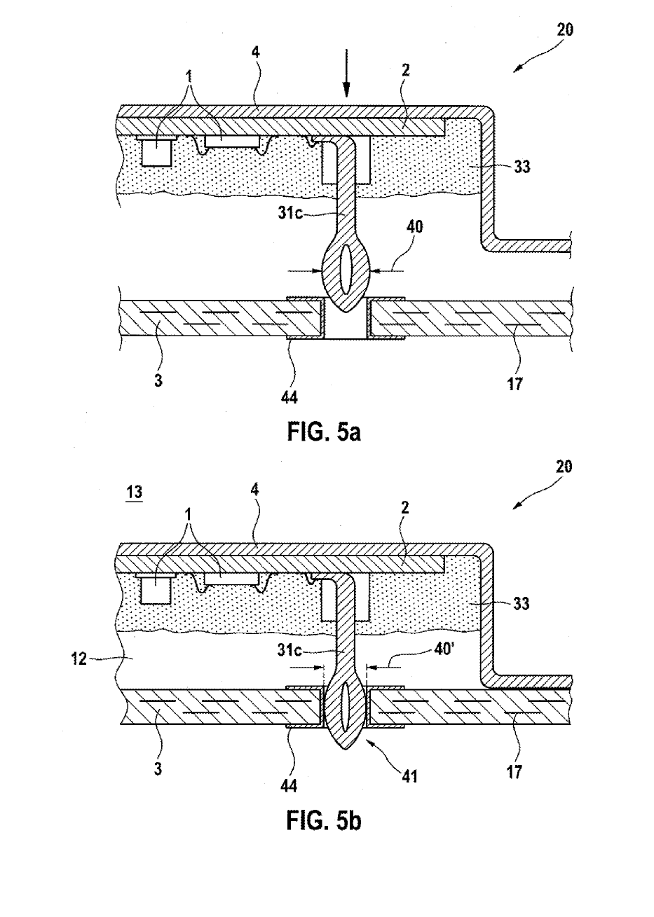

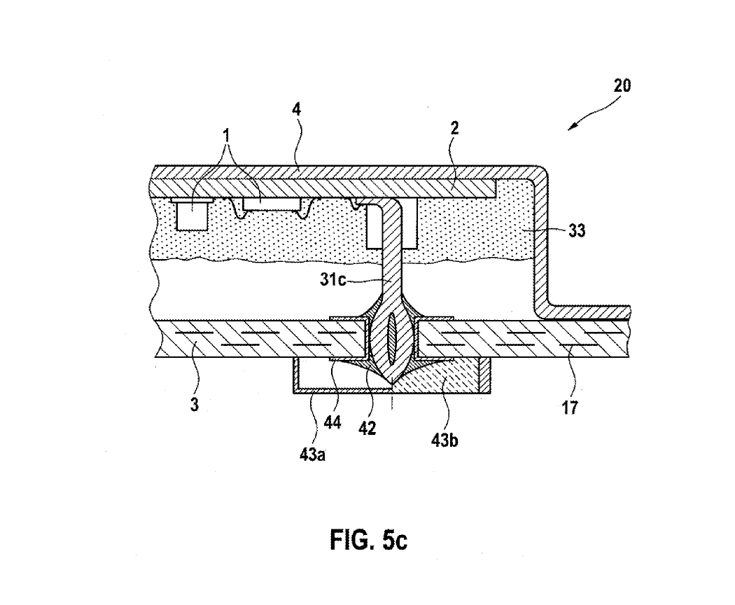

FIGS. 5a-c show an exemplary refinement of an electrical connecting element according to the present invention.

### EMBODIMENTS OF THE INVENTION

Referring again to FIG. 2, an exemplary refinement of an electronics module according to the present invention is illustrated.

The inventive layered structure of an electronics module according to the present invention is illustrated in FIG. 2 as follows: a plate element 3 is followed by a covering element 4 which, as a result of its elongated side faces resting on the plate element 3 can also perform the function of a carrier element. By way of example, an aluminum plate or steel plate with 1-2 mm plate thickness, if appropriate thickened by beads, can be used as a covering element 4. The covering element 4 can delimit the dimensions of the entire electronics module 20 or else can delimit the relevant region of the circuit carrier element 2 and a fastening of the covering element 4 and plate element 3.

The circuit carrier element 2, for example, an LTCC or microcircuit board with electronic components 1 is fastened to a trough-shaped base 30 of the possibly metallic covering element 4, which can be manufactured, for example, by deep drawing. A thermally conductive adhesive 8 can for example be used for the fastening.

Furthermore, a board-to-board connection 31 and an electrical connecting element which electrically connects the electrical components 1 to the plate element 3 are arranged on the circuit carrier element 2. These electrical connecting elements 31 can be embodied for example as micromechanical components in various embodiments. It is essential to the invention here that during the fitting of the covering element 4 and plate element 3, the conductive connection between the circuit carrier element 2 and the plate element 3, in particular the conductor elements 17 thereof, takes place automatically. In this context, the term automatically is to be understood as meaning the provision of an electrical connection without further working steps, in particular without, for example, a separate soldered connection or the like by means of bonds or a cable element which only requires a step of fastening onto the plate element 3.

The electrical connecting element 31 is embodied for example as a sprung sheet metal tongue, while the electrical connecting element 31a functions in a way comparable to a knife/fork contact. The electrical connecting element 31b is also embodied for example as a sprung pin.

Such board-to-board connections can be fastened cost-effectively, for example, as an SMD component, on the circuit carrier element 2, for example, by a reflow soldering process. Corresponding board-to-board connections can be implemented in one signal variant, that is to say a low-power variant, as well as a power variant or high-power variant.

On the inside of the plate element 3 there are conductor elements 17. For example, the plate element 3 can be implemented as a conventional printed circuit board element with internal copper conductors 17, which are protected by individual laminate layers. The conductor elements 17 implementing the electrical equipment between the interior 12 of the electronics module 20 and the exterior 13, that is to say between the electrical components 1 and the external functional elements such as, for example, plugs and sensors not illustrated in FIG. 2.

The plate element 3 and covering element 4 can be sealed either by a bonded connection 10, in particular a sealing bonded connection, or alternatively by an elastomer seal 11. In this context, the covering element 4 is either secured by the bonded connection 10 or alternatively by an additional mechanical fastening element 32, for example a rivet element.

Centering elements can also be provided between the plate element 3 and the covering element 4, said centering elements being configured in particular, to make available the board-to-board connection of the electrical connecting element 31 with the result that the latter reliably meet the plug connections or contact pads on the plate element 3, which are opposite or complementary to the electrical connecting elements 31.

The electronic component 1′, which for example, gives rise to high dissipated heat \dot{Q} is also illustrated in FIG. 2. Said component 1′ is separate from the circuit carrier element 2 and the components 1 arranged thereon and can be connected, for example, directly to the covering element 4, for example with thermal bonding adhesive. Improved conducting away of heat can be implemented for the electronic component 1′ by virtue of the direct connection of component 1′ as opposed to the indirect connection of the components 1 via the circuit carrier element 2. For example, bonding or conductive adhesion can be used as electrical contact-forming equipment between the component 1′ and the circuit carrier element 2.

In order to protect the electronic components 1, 1′ and the carrier element 2 as well as the contact-forming equipment thereof, the trough 30 can be filled with a casting material 33, for example a suitable curing gel. In this context, as much casting material 33 as possible is preferably filled into the trough 30 of the covering element 4 with the result that essentially only the electrical connecting elements 31 then project out. This permits the functionality of the cast electronic components 1, 1′ and the circuit carrier element 2 to be checked after the process of filling the base 30 of the covering element 4 with casting material 33.

A via 34 is illustrated in the plate element 3 in FIG. 2, which via can be closed off, for example, by a soldering process or a plug, which after the covering element 4 and plate element 3 have been fitted, permits checking of the seal, for example, through excess pressure and/or by filling with a suitable inert gas. Likewise, it is conceivable to introduce the casting material 33 through the via 34 in the mounted state.

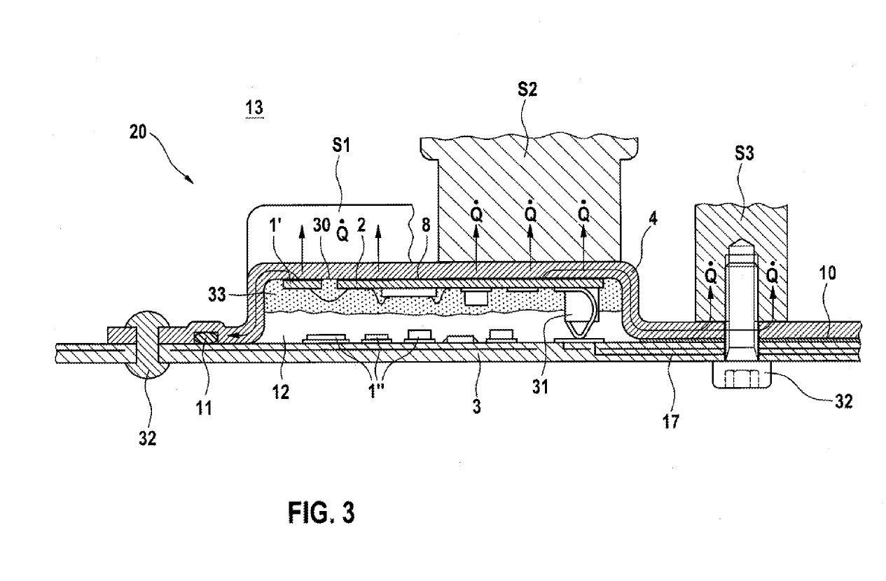

Referring again to FIG. 3, a further exemplary refinement of an electronics module according to the present invention is illustrated.

Here, FIG. 3 essentially corresponds to the refinement described above with respect to FIG. 2. What is changed compared to FIG. 2 here is that the plate element 3 also has further electronic components 1″ which can also be arranged on a further circuit carrier 2 and mounted on the plate element 3. An electrical connection of the electronic components 1″ can be implemented for example, by means of the conductor elements 17 arranged in the plate element 3. In this context, the electronic components 1″ can preferably be components with low dissipated heat since possibly less dissipated heat can be conducted away via the plate element 3 than, for example, via the covering element 4, in particular if the latter is embodied as a metal element.

An electronics module can be implemented, for example, in a particularly compact way in two planes.

The dissipated heat of the electronic components 1, 1′, 1″ in FIG. 3 can be output via heat sinks, for example, cooling fins S1, to air oil or spray oil and/or to a heat sink S2 which is pressed on, soldered on, welded on or bonded on and is preferably of metallic design. A mechanical fastening element 32 which is embodied, for example, as a screwed connection is also illustrated in FIG. 3 on the right-hand side, and in addition a heat sink S3 is fastened to the covering element 4.

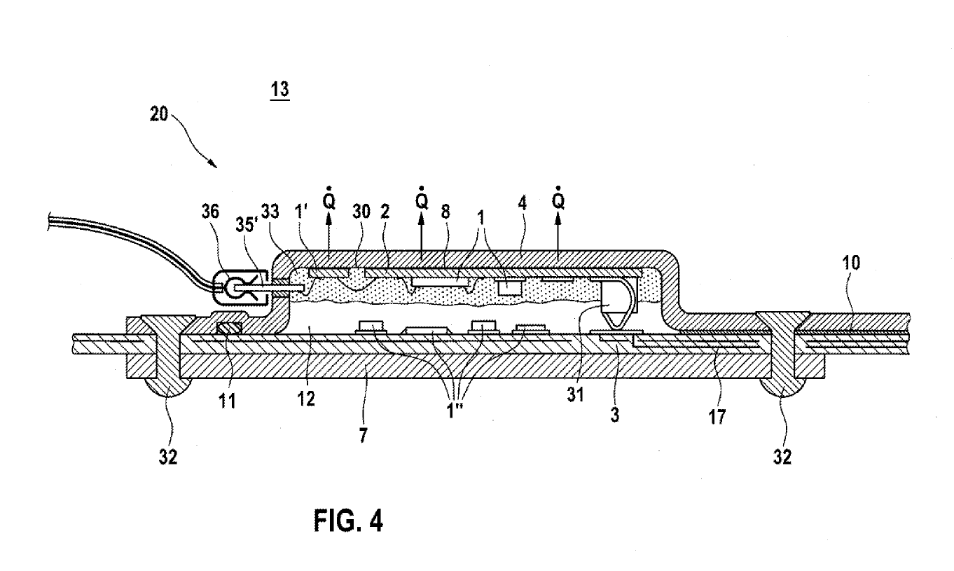

Referring again to FIG. 4 a further exemplary refinement of an electronics module according to the present invention is illustrated.

A carrier element 7 is also provided in FIG. 4, arranged on the plate element 3 and opposite the covering element 4. The carrier element 7 prevents or at least reduces, for example, possible output buckling of the plate element 3 (in the direction of the carrier element 7 which is now mounted), for example, caused by an internal rise in pressure due to temperature. Carrier element 7 can be formed, for example, from plastic or metal. In this context, the covering element can be embodied, for example, as a metal, and likewise embodied as a heat sink. The carrier element 7 can also be mounted on the plate element 3 and the covering element 4 by means of mechanical fastening elements 32.

Furthermore, a possible path 35′ through the covering element 4 is illustrated in FIG. 4. Metal pins which are bonded in by a vitrified seal are conceivable here, contact being made with said metal pins, for example, on the outside of the covering element 4 by means of a plug connection 36 or welded connection. In this context, the path 35′ can be, for example, a high-current path and can be, for example, connected to the electrical high-power component 1′. As a result, the plate element 3 does not necessarily have to be capable of conducting high current and can therefore be manufactured more cost-effectively.

It is also conceivable for the path 35 to be embodied as an optical communication path and therefore to be able to make available a, for example electrically isolated, communication connection from the interior of the electronics module to the outside. In this case, the plug connection 36 could be embodied as an optical glass fiber.

Also referring to FIGS. 5a to c, an exemplary refinement of an electrical connecting element according to the present invention is illustrated.

FIG. 5a shows a detail of the electronics module 20 with the electrical connecting element 31c, embodied as a pin with a sprung region 40. The sprung region 40 and a contact point 44 in the plate element 3 are matched to one another here in such a way that during an insertion process the sides of the sprung region 40 make contact with the side faces of the contact point 44 and therefore implement an automatic connection of the connecting element 31c and contact point 44 during the fitting process.

In FIG. 5a the dimensions of the sprung region 40 are somewhat larger than the opening of the contact point 44, wherein the sprung region 40 is still to be capable of being inserted into the contact point 44. FIG. 5a shows a state in which the covering element 4 and the plate element 3 are not yet fitted one onto the other and therefore not yet mounted. The contact point 44 can also be electrically conductively connected to the conductor elements 17 of the plate element 3.

In FIG. 5b, the cover element 4 and the plate element 3 are fitted one onto the other and therefore mounted. In this context, a conductive connection between the circuit carrier element 2 and components 1, 1′, 1″ and the conductor element 17 is implemented via the contact element 31c and the contact point 44 by sliding the sprung region 40 of the contact element 31c into the contact point 44. In the inserted state, the sprung region 40 is pressed together to form the sprung region 40′ and as a result comes to rest in a frictionally locking fashion on the side faces of the contact point 44, as a result of which the electrical connection of the individual components 1, 1′, 1″, 2, 31c to 40, 44 and 17 is produced.

An embodiment of the contact point 44 is illustrated, for example, in FIGS. 5a-c in an unsealed form 41, penetrating the plate element. In order to seal off the inner region 12 from the outer region 13 of the electronics module 20 it is possible, as illustrated in FIG. 5c, for the contact point 44 to be suitably closed off 42 with the contact element 31c introduced, for example, by welding, a soldering process or suitable adhesion, which also at the same time can provide insulation or covering of the contact point 44. Alternatively, in order to protect the outwardly open contact point on the plate element 3 it is possible to provide a further covering element 43a or else a casting frame in order to protect the contact point 44 with casting material 43b.

Likewise it is conceivable that the contact point 44 itself merely forms for example, a trough-shaped depression in the plate element 3, and at the same time does not completely, rather only partially, penetrates the plate element 3. Depending on the specific refinement of the sprung region 40, the latter can also come into contact with the side faces of the contact point 44 in a refinement such as that described above, and in doing so brings about the conductive connection without the plate element 3 having to have openings passing through it. In this case, protection according to components 43a or 43b is not necessary, since the outside of the plate element 3 is of continuous design without openings for contact elements 31.

1. An electronics module for a vehicle, comprising
a plate element;
a circuit carrier element;
a covering element;
an inner region; and
an outer region;
wherein the plate element is configured to provide at least one conductive connection between the inner region and the outer region in order to electrically connect the circuit carrier element;
wherein the circuit carrier element is positioned on the covering element,
wherein at least one electrical connecting element is positioned between the circuit carrier element and the plate element; and
wherein the at least one electrical connecting element is an automatic connecting element configured to automatically provide an electrically conductive connection between the circuit carrier element and the at least one conductive connection of the plate element when the covering element and the plate element are fitted.

2. The electronics module as claimed in claim 1, wherein the automatic connecting element is at least one of a sprung, sprung needle eyelet, tolerance-compensating, self-centering and plug connecting element.

3. The electronics module as claimed in claim 1, wherein at least one of:
the plate element is a circuit board element;
the plate element has a further circuit carrier element; and
the plate element has electrical components.

4. The electronics module as claimed in claim 1,
wherein a heat sink is positioned on the cover element; and
wherein the heat sink is configured to dissipate heat of the circuit carrier element.

5. The electronics module as claimed in claim 1,
wherein a carrier element is positioned on the plate element, at least in a partial region; and
wherein the carrier element is configured to at least one of perform stabilization and output dissipated heat.

6. The electronics module as claimed in claim 1,
wherein the cover element has at least one conductor element which is configured to penetrate the cover element; and
wherein the conductor element is connected to at least one of the circuit carrier element and at least one electronic component.

7. The electronics module as claimed in claim 6, wherein the conductor element is an electrical high-power conductor element, and the at least one conductive connection of the plate element is a low-power connection.

8. The electronics module as claimed in claim 6, wherein the conductor element is an optical conductor element.

9. A transmission control unit for a vehicle, having an electronics module that includes:
a plate element;
a circuit carrier element;
a covering element;
an inner region; and
an outer region;
wherein the plate element is configured to provide at least one conductive connection between the inner region and the outer region in order to electrically connect the circuit carrier element;
wherein the circuit carrier element is positioned on the covering element,
wherein at least one electrical connecting element is positioned between the circuit carrier element and the plate element; and
wherein the at least one electrical connecting element is an automatic connecting element configured to automatically provide an electrically conductive connection between the circuit carrier element and the at least one conductive connection of the plate element when the covering element and the plate element are fitted.

10. The transmission control unit according to claim 9, wherein the transmission control unit is comprised by a transmission for a vehicle.

11. A motor vehicle, having at least one of:
(i) an electronics module that includes:
a plate element;
a circuit carrier element;
a covering element;
an inner region; and
an outer region;
wherein the plate element is configured to provide at least one conductive connection between the inner region and the outer region in order to electrically connect the circuit carrier element;
wherein the circuit carrier element is positioned on the covering element,
wherein at least one electrical connecting element is positioned between the circuit carrier element and the plate element; and
wherein the at least one electrical connecting element is an automatic connecting element configured to automatically provide an electrically conductive connection between the circuit carrier element and the at least one conductive connection of the plate element when the covering element and the plate element are fitted;
(ii) a transmission control unit that comprises the electronics module; and
(iii) a transmission that comprises the transmission control unit.
